(19) United States
(12) Patent Application Publication
(10) Pub. No.: US 2005/0140252 A1
(43) Pub. Date: Jun. 30, 2005

(54) Tuning fork type piezoelectric resonator element and method for producing a tuning fork type piezoelectric resonator

(76) Inventors: Takuya Miyata, Nagano-ken (JP); Toshinari Jokura, Okaya-shi (JP); Atsushi Oshiro, Nagano-ken (JP)

Correspondence Address: ANDERSON, KILL & OLICK, P.C., 1251 AVENUE OF THE AMERICAS, NEW YORK,, NY, 10020-1182, US

(21) Appl. No.: 10/999,617

(22) Filed: Nov. 29, 2004

(30) Foreign Application Priority Data
Nov. 27, 2003 (JP) 2003-397048
May 24, 2004 (JP) 2004-153358

(51) Int. Cl. H03H 9/21

(52) U.S. Cl. 310/370

(57) ABSTRACT

A tuning fork type piezoelectric resonator element having a wide operating temperature range and method of manufacture comprising a base having two sides and opposite ends,a plurality of resonating arms 18 protruding from one end of the base 12, a plurality of mount electrodes 16 corresponding in number to said resonating arms disposed at an opposite end of the base 12 and being connected by lead terminals to the mount electrodes using a conductive joining material. The mount electrodes 16 are spaced a minimum distance apart sufficient to prevent shorting caused by diffusion of the conductive joining material 22 for joining lead terminals 32 to the mount electrodes 16 with the lead terminals connected to said mount electrodes without forming a bend in the lead terminals at the end thereof adjacent the mount electrodes and with the width of the base along each side thereof set to a value that permits the lead terminals to be linearly joined to the mount electrodes.

### TECHNICAL FIELD

The present invention relates to a tuning fork type piezoelectric resonator element and a method for producing a tuning fork type piezoelectric resonator. More particularly, the present invention relates to a tuning fork type piezoelectric resonator element that is required to be highly reliable and a method for producing a tuning fork type piezoelectric resonator.

### BACKGROUND ART

One type of tuning fork type piezoelectric resonator is a cylinder tuning fork type piezoelectric resonator having a tuning fork type piezoelectric resonator element disposed in a cylindrical container. FIG. 5 is a sectional view of a related cylinder tuning fork type piezoelectric resonator. A tuning fork type piezoelectric resonator element 100 comprises a base 102 and a plurality of resonating arms 104 extending from the base 102. An excitation electrode (not shown) is disposed at each vibratory arm 104, and mount electrodes 106 for connection to the excitation electrodes are disposed at the base 102. The tuning fork type piezoelectric resonator element 100 is disposed in a cylindrical container 108 having one open end so that the base 102 opposes the open end of the container 108. The container 108 is hermetically sealed by joining a plug 116 to the open end of the container 108. The plug 116 is formed by hermetically sealing a plurality of lead terminals 114 comprising inner leads 110 and outer leads 112.

The tuning fork type piezoelectric resonator element 100 is small in size which permits a large number of tuning fork type piezoelectric resonator elements to be formed from one piece of wafer. Therefore, the width of the base 102 of the tuning fork type piezoelectric resonator element 100 is smaller than the distance between the lead terminals 114.

Consequently, the ends of the leads 110 adjacent the mount electrodes 106 (“inner ends”) are bent with a jig so as to reduce the distance between the lead terminals 114 in accordance with the width of the base 102. Thereafter, the inner leads 110 and the mount electrodes 106 are electrically and mechanically joined with solder 118. An arrangement of a tuning fork cylinder piezoelectric resonator formed in this manner is disclosed in Japanese Unexamined Patent Application Publication No. 59-225605.

In recent years, vehicles are computerized and have various electronic devices installed which require time synchronization. A tuning fork type piezoelectric resonator is installed in a vehicle in order to generate a control clock for such various electronic devices. Since a tuning fork type piezoelectric resonator installed in a vehicle is constantly being vibrated, it uses a cylindrical metallic container 108, such as that shown in FIG. 5, in order to prevent breakage by the vibration. In the tuning fork type piezoelectric resonator for vehicle use, mount electrodes 106 and lead terminals 114 at a piezoelectric resonator element 100 are joined with solder that provides excellent vibration resistance.

The tuning fork type piezoelectric resonator for vehicle use may be disposed in the engine compartment of a vehicle. In this location the tuning fork type piezoelectric resonator is exposed to varying temperatures depending upon the operating condition of the vehicle. More specifically, in midwinter, the temperature in the engine compartment may be less than 0° C. when the engine is stopped, whereas the temperature may rise to about 100° C. when the engine is operating. Therefore, the tuning fork type piezoelectric resonator for vehicle use is required to be highly reliable so that, for example, it will operate stably over a long period of time and in a wide temperature range which can vary from −40° C. to +125° C. Consequently, in the tuning fork type piezoelectric resonator for vehicle use, the mount electrodes 106 and the lead terminals 114 are joined with a high temperature solder preferably containing 90 wt % lead (Pb) and 10 wt % tin (Sn).

However, when the tuning fork type piezoelectric resonator is disposed in the engine compartment of an automobile where temperature variations fluctuate repeatedly between high and low temperatures and over a long period of time, the solder particles joining the mount electrodes and the lead terminals may diffuse due to temperature stress. This may cause the diffused solder to protrude from each mount electrode 106 resulting in the diffused solder from adjacent mount electrodes 106 making contact with one another which may cause shorting of the mount electrodes. In addition, the resonating arms may be chipped or bent when the container of the tuning fork type piezoelectric resonator and the resonating arms of the tuning fork type piezoelectric resonator element come into contact with each other due to intense vibration of the vehicle.

The inner leads are fixed and joined to the mount electrodes in the tuning fork type piezoelectric resonator element by fusing solder that was previously applied to the inner leads. However, in bending the inner leads, the applied solder are peeled and raised at portions of the inner leads that are rubbed by a jig for bending the inner leads. That is, what are called solder burrs are produced. When the solder burrs are produced and the inner leads are joined to the mount electrodes, a short circuit may occur due to the raised solder at one of the mount electrodes or inner leads coming into contact with another of the mount electrodes or inner leads.

The tuning fork type piezoelectric resonator element of the present invention is not susceptible to temperature change even over a wide temperature range and has increased shock resistance.

### SUMMARY OF THE INVENTION

The tuning fork type piezoelectric resonator element of the present invention comprises a base having opposite ends, a plurality of resonating arms protruding from one end of the base, a plurality of mount electrodes disposed at the other end of the base in substantial alignment with the resonating arms, a corresponding plurality of lead terminals extending from the mount electrodes and a solder conductive joining material for joining the lead terminals to the mount electrodes wherein the mount electrodes are spaced apart a minimum distance of at least about 60 μm so as to prevent shorting of the conductive joining material when subjected to repeated temperature changes. By virtue of this structure, the shorting of the mounting electrodes do not occur even if the conductive joining material is diffused by being subjected to temperature stress produced by a repetition of a temperature cycle of low temperature and high temperature.

It is desirable that the distance between the mount electrodes be equal to or greater than at least about 60 μm. Experiments were conducted on a tuning fork type piezoelectric resonator having lead terminals joined to mount electrodes using high temperature solder. The experiments show that, when a temperature cycle in the temperature range of from −40° C. to +125° C. is repeated 1000 times, the length of diffused solder protruding from each mount electrode (fillet length) is approximately 15 μm at the maximum. Therefore, if the distance between the mount electrodes is equal to or greater than 60 μm, it is possible to prevent shorting of the mount electrodes and, thus, to maintain the performance of the tuning fork type piezoelectric resonator when the temperature cycle in the aforementioned temperature range that is generally required for a tuning fork type piezoelectric resonator for vehicle use is repeated 1000 times.

When the temperature cycle in the temperature range of from −40° C. to +125° C. is repeated 2000 times (corresponding to approximately 10 years of vehicle use), the length of the solder protruding from each mount electrode is approximately 25 μm at the maximum. Therefore, if the distance between the mount electrodes is 60 μm, shorting of the mount electrodes can be prevented even if the temperature cycle is repeated 2000 times (corresponding to approximately 10 years of vehicle use). However, in order to more safely and reliably prevent shorting of the mount electrodes when the aforementioned temperature cycle is repeated 2000 times, it is desirable for the distance between the mount electrodes to be equal to or greater than 80 μm. Further, in order to reliably prevent shorting of the mount electrodes when a vehicle is used for an even longer period of time, it is desirable that the distance between the mount electrodes be equal to or greater than 120 μm.

In accordance with the present invention it was discovered that the width of the base in the direction transverse to the lead terminals may be extended to allow the lead terminals to be linearly joined without reducing the area of the mount electrodes even if the distance between the mount electrodes is increased, so that it is possible to provide mount electrodes that are large enough for joining the lead terminals thereto without bending the ends of the lead terminals. In addition, since it is no longer necessary to bend the lead terminals, the problem of the conductive joining material applied to the lead terminals being peeled and raised due to rubbing between the lead terminals and a jig for bending the lead terminals does not occur. Therefore, it is possible to eliminate the problem of a short circuit failure caused by the conductive joining material at one lead terminal coming into contact with another lead terminal or another conductive joining material.

Two sides of each vibratory arm may have the same length, and the resonating arms may extend symmetrically with respect to a centerline of the base. By virtue of this structure, it is possible to maintain vibrational balance when the resonating arms undergo bending vibration, and, thus, to achieve a predetermined oscillatory frequency.

Each vibratory arm may be disposed inwardly from the sides of the base, and the base may have an arc shape disposed between the resonating arms defined by a forked portion and with each side of the base having rounded shoulders of the same curvature as the forked portion disposed between the sides of the base and the resonating arms. By virtue of this structure, since the curvature of the inner side of the resonating arms and the curvature of the outer side of the resonating arms are the same, the resonating arms are all of the same length. Therefore, it is possible to maintain vibrational balance when the resonating arms undergo bending vibration, and, thus, to achieve a predetermined oscillatory frequency.

An end of each vibratory arm may have a convex surface. By virtue of this structure, since the problem of, for example, cracking or bending of the resonating arms caused by the resonating arms coming into contact with a container containing the tuning fork type piezoelectric resonator element is eliminated, it is possible to increase shock resistance.

Both sides of the base extending in the direction in which the resonating arms extend may have cut portions extending into the base. By virtue of this structure, it is possible to reduce vibration leakage caused by bending vibration of the resonating arms, so that the performance of the tuning fork type piezoelectric resonator is increased.

The width at the end of the base 12 (FIG. 2) extending perpendicularly to the resonating arms may be greater than the width of the base extending at least over the portion where the mount electrodes are formed. By virtue of this structure, only the portion of the base where the mount electrodes are formed is enlarged.

The tuning fork type piezoelectric resonator of the present invention is formed by a method which comprises the steps of setting the distance between the mount electrodes to a value of at least 60 μm which prevents shorting caused by diffusion of the conductive joining material while; setting the width of the base to a value sufficient to allow the lead terminals to be linearly joined to the mount electrodes essentially without bending; and determining the location of one of the resonating arms with respect to the base so that curvatures of the base at the locations where the resonating arms are connected to the base are the same. By virtue of this arrangement, it is possible to eliminate the problem of shorting of the mount electrodes caused by dispersion of the conductive joining material. In addition, since the width of the base is increased at least at one end thereof, it is possible for the area of the mount electrodes to be large enough for joining the lead terminals thereto. Further, since conductive adhesive applied to the lead terminals does not rub against a jig and become raised, a short circuit failure does not occur. Still further, by forming the resonating arms with the same length, it is possible to maintain vibrational balance when the resonating arms undergo bending vibration, and, thus, to achieve a predetermined oscillatory frequency.

### BRIEF DESCRIPTION OF THE DRAWINGS

FIG. 1 is a sectional view of a tuning fork type piezoelectric vibrator in accordance with a first embodiment of the present invention.

FIG. 2 is a plan view of a tuning fork type piezoelectric resonator element in accordance with the first embodiment.

FIG. 3 is a plan view of a tuning fork type piezoelectric resonator element in accordance with a second embodiment of the present invention.

FIG. 4 is a plan view of a tuning fork type piezoelectric resonator element in accordance with a third embodiment of the present invention.

FIG. 5 is a sectional view of a related cylinder tuning fork type piezoelectric vibrator.

FIG. 6 illustrates the relationship between a temperature cycle and solder fillet.

FIG. 7 is a plan view of a tuning fork type piezoelectric resonator element in accordance with a fourth embodiment of the present invention. and

FIG. 8 is a sectional view taken along line A-A of FIG. 7.

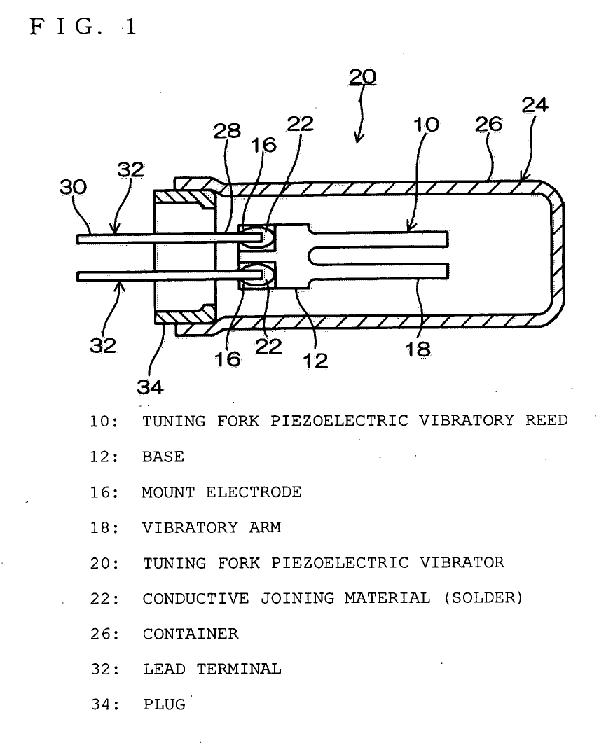

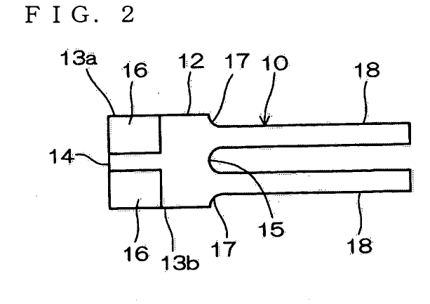

The preferred embodiments of the tuning fork type piezoelectric resonator element and method for producing a tuning fork type piezoelectric resonator in accordance with the present invention will hereafter be described in detail. The first embodiment will be described in connection with FIG. 1 and FIG.2.

In FIGS. 1 and 2, The resonator element 10 includes conventional excitation electrodes (not shown) which are disposed in the resonating arms. The tuning fork type piezoelectric resonator element 10 comprises a base 12 of substantially rectangular configuration having opposite sides 13a and 13b and opposite ends, a plurality of resonating arms 18 extend from one end of the base 12which has a curved portion 15 disposed between the pair of resonating arms 18 and has curved shoulders 17 disposed between the sides 13a and 13b of the base 12 and the corresponding resonating arms 18 respectively. The opposite end 14 of the base 12 is flat and lies perpendicular to the resonating arms 18. Mount electrodes 16 are formed adjacent the flat end 14 of the base 12 at each opposite corner of the sides 13a and 13b respectively and are connected to the excitation electrodes (not shown) of the resonating arms 18.

The width of the base 12 at the end 14 which lies in a direction perpendicular to the direction of the resonating arms 18 is greater than the lateral distance between lead terminals 32 as is shown in FIG. 1. The lead terminals 32 are electrically and mechanically joined to the mount electrodes 16 located on both corners of the end 14 of the base 12 using a conductive joining material 22 having increased heat resistance, such as a solder 22 composition of lead and tin in a mixing ratio adjusted for high heat resistance.

The distance between the mount electrodes 16 is greater than that in the related tuning fork type piezoelectric resonator element 10, and does not allow shorting of the mount electrodes 16 even if solder diffusion occurs when temperature stress produced by repetition of a temperature cycle of low temperature and high temperature is exerted upon the solder 22. Since the diffusion distance of the solder changes with the difference between low temperature and high temperature, the diffusion distance of the solder in a specification temperature of the tuning fork type piezoelectric resonator 20 is previously checked, and the distance between the mount electrodes 16 is set greater than this previously checked distance. In this embodiment, the preferred minimum distance between the pair of mount electrodes 16 is 60 μm.

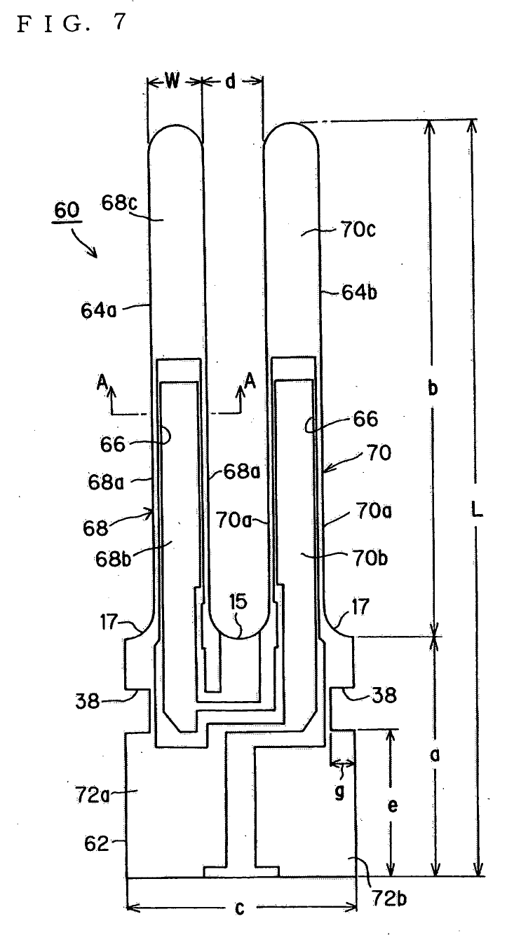

The lead terminals 32 are joined to the mount electrodes 16 in the tuning fork type piezoelectric resonator element 10 using a solder 22 for high-temperature application containing 90 wt % lead and 10 wt % tin. The inventor et al. conducted a temperature cycling test in a range of from −40° C. to +125° C. on the joined lead terminals 32 and the mount electrodes 16 in order to observe the diffusion state of the solder with a microscope. The results are shown in FIG. 6. In FIG. 6, the horizontal axis represents the number of temperature cycles in the range of from −40° C. to +125° C., and the vertical axis represents the maximum length of protrusion of the solder from the mount electrodes in each tuning fork type piezoelectric resonator element (that is, fillet length) in μm. The temperature cycling test was carried out in a cycle of one hour such that the temperature is kept at −40° C. for 30 minutes, then, at +125° C. for 30 minutes, and then at −40° C. for 30 minutes.

As shown in FIG. 6, when 1000 cycles of the temperature cycling required with regard to a heat resistance specification for vehicle use are to be performed, the fillet length is a little less than 15 μm at the maximum. Therefore, if the distance between the mount electrodes 16 is 60 μm, the solder fillets at the respective mount electrodes 16 will not contact each other, thereby making it possible to prevent shorting of the mount electrodes 16. When 2000 cycles of the temperature cycling corresponding to of the order of 10 years of use of a vehicle are to be performed, the maximum fillet length of the solder is approximately 25 μm. Therefore, if the distance between the mount electrodes is equal to or greater than 60 μm, it is possible to prevent shorting of the mount electrodes. However, in order to more reliably prevent the shorting of the mount electrodes, it is desirable for the distance between the mount electrodes to be equal to or greater than 80 μm. If the distance between the mount electrodes is equal to greater than 80 μm, the distance between the fillets is at least approximately equal to or greater than 30 μm, so that shorting does not occur. In order to safely and reliably prevent shorting of the mount electrodes when more than 2000 cycles of the temperature cycling which may produce larger fillets are to be performed, the distance between the mount electrodes is equal to or greater than 120 μm.

From the aforementioned results, the distance between the mount electrodes 16 can be set at 60 μm or greater, at 80 μm or greater, and at 120 μm or greater in accordance with the required number of cycles of temperature cycling.

Moreover, if the width of the base 12 is increased due to an increase in the distance between the mount electrodes 16, the area of the mount electrodes 16 will still be large enough for joining the lead terminals 32. see comment Therefore, a reduction in the area of the mount electrodes caused by simply increasing only the distance between the mount electrodes compared to the prior art related tuning fork type piezoelectric resonator element does not occur.

The lengths of linear portions of the left and right sides of the resonating arms 18 extending from the base 12 are the same. In the embodiment, shown in FIG. 2, the pair of the resonating arms 18 are disposed at symmetrical positions situated inwardly of the opposite sides 13a and 13b of the base 12. The end of the base 12 from which the resonating arms 18 extend is formed with an arc shape disposed between the pair of resonating arms 18 to define a forked portion 15 and has shoulders 17 disposed between the sides 13a and 13b and the respective resonating arms 18 with each shoulder 17 having a curvature conforming to the curvature of the forked portion 15 on the side opposite the respective shoulder. Therefore, the shapes of the resonating arms 18 are symmetrical with respect to a centerline extending in the lengthwise direction of the resonating arms 18. Since the plurality of such resonating arms 18 extend from the base 12, it is necessary for the shapes of all of the resonating arms 18 to be the same. Therefore, in the tuning fork type piezoelectric resonator element 10, the resonating arms 18 extend from the base 12 symmetrically with respect to the centerline of the base 12 extending in the direction of extension of the resonating arms 18. Thus, the curvature of the portion disposed inwardly of the resonating arms 18 and the curvature of the portion disposed outwardly of the resonating arms 18 are the same(mirror image) Since the natural frequency of the tuning fork type piezoelectric resonator element is determined by the length and the width of the resonating arms, the length and the width of the resonating arms 18 in the embodiment are the same as those of the resonating arms in the related art.

The above-described tuning fork type piezoelectric resonator element 10 is disposed in a cylinder 24 for forming the cylinder tuning fork type piezoelectric resonator 20. of the present invention shown in FIG. 1. More specifically, the tuning fork type piezoelectric resonator element 10 is disposed in a cylindrical metallic container 26 having an open end adjacent the base 12. The container 26 is hermetically sealed at the open end by inserting a plug 34 into the open end of the container 26. The plug 34 is formed by hermetically sealing the lead terminals 32 to form linear inner leads 28 internal of the container 26 and outer leads 30 which lie external of the container 26. The inner leads 28 and the mount electrodes 16 are electrically and mechanically joined with a solder 22 having increased heat resistance.

A preferred method for producing the tuning fork type piezoelectric resonator element 10 of the present invention for use in the tuning fork type piezoelectric resonator 20 will be hereafter described. First, the distance of solder diffusion at a specification temperature of the tuning fork type piezoelectric resonator 20 is checked in order to determine whether the distance between the mount electrodes 16 is greater than the checked distance. Since the area of the mount electrodes 16 is reduced when the distance between the mount electrodes 16 is increased, the joining strength of the mount electrodes 16 and the lead terminals 32 is reduced. Therefore, the width of the base 12 at which the mount electrodes 16 are disposed is determined so that the lead terminals 32 can be linearly joined, and the mount electrodes 16 is widened in the direction in which the width of the base 12 is increased in order to ensure joining strength of the mount electrodes 16 with the lead terminals 32.

Next, in order to form the left and right sides of one of the resonating arms 18 with the same length, the curvature at the location where the vibratory arm 18 and the base 12 are connected is determined. This is because, if the left and right sides of the vibratory arm 18 have different lengths, a predetermined oscillatory frequency cannot be achieved due to a loss in bending vibrational balance. The location of the vibratory arm 18 extending from the base 12 is determined so that the curvatures at the resonating arms 18 are the same. Accordingly, the shape of the tuning fork type piezoelectric resonator element 10 is determined.

In this way, since the distance between the mount electrodes 16 disposed at the tuning fork type piezoelectric resonator element 10 is increased, shorting of the mount electrodes 16 caused by the solder 22 of each mount electrodes 16 coming into contact with each other due to solder diffusion does not occur even if temperature stress is applied. If the mount electrodes 16 are not shorted even if solder diffusion occurs, various characteristics of the tuning fork type piezoelectric resonator 20 are not affected. In addition, the width of the base 12 where the mount electrodes 16 are disposed is greater than the distance between the lead terminals 32, and the mount electrodes 16 is larger in the direction in which the width of the base 12 is increased. Therefore, the area of the mount electrodes 16 is not reduced, so that the joining strength of the mount electrodes 16 and the lead terminals 32 can be ensured. Further, since the width of the base 12 is large enough with respect to the plug 34, the supporting capability is greater than that in a related tuning fork type piezoelectric resonator element. Still further, since the lead terminals 32 can be linearly joined to the mount electrodes 16, solder burrs produced when the inner leads are bent with a jig are not produced, thereby making it possible to eliminate short circuit failure. Consequently, it is possible to provide a tuning fork type piezoelectric resonator 20 which is required to be highly reliable.

Since the inner leads 28 are not bent, it is possible to increase productivity of the tuning fork type piezoelectric resonator 20. Since a large investment in plant and equipment is not required, it is possible to minimize an increase in cost of producing a tuning fork type piezoelectric resonator element 10 having a new shape.

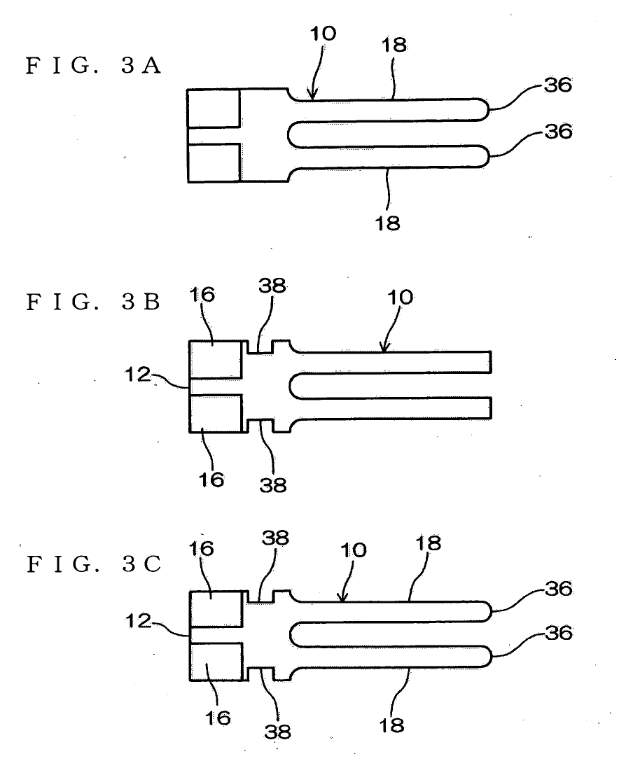

A second embodiment will now be described. Since the second embodiment is a modification of the tuning fork type piezoelectric resonator element 10 of the first embodiment, corresponding parts to those of the first embodiment will be given the same reference numerals, and will not be described below. FIG. 3 is a plan view of a tuning fork type piezoelectric resonator element in accordance with the second embodiment. In FIG. 3, excitation electrodes that are disposed at resonating arms are not shown.

When a tuning fork type piezoelectric resonator 20 is used in an environment in which an intense vibration is applied thereto, and is installed and used in, for example, a vehicle, resonating arms 18 may become, for example, chipped or bent as a result of a tuning fork type piezoelectric resonator element 10 being shaken and coming into contact with a container 26. In addition, even when producing the tuning fork type piezoelectric resonator 20, the resonating arms 18 may become, for example, cracked or chipped when corners of the resonating arms 18 get caught by, for example, a manufacturing jig. Therefore, ends of the resonating arms 18 have convex curved portions 36 (see FIG. 3(a)). The curvatures of the curved portions 36 of the left and right resonating arms 18 are the same. The curved portions 36 are formed by etching. When the ends of the resonating arms 18 are curved, they will not chip or bend compared to the case in which the ends of the resonating arms 18 are angular. Therefore, shock resistance is increased, thereby making it possible to provide a highly reliable tuning fork type piezoelectric resonator element 10. In addition, since, for example, cracking or chipping does not occur when producing the tuning fork type piezoelectric resonator 20, yield is increased, so that the cost of manufacturing the tuning fork type piezoelectric resonator 20 can be reduced.

When the tuning fork type piezoelectric resonator element 10 vibrates, the resonating arms 18 undergo bending vibration. Here, what is called vibration leakage may occur in which the vibration is transmitted to portions at the base 12 where mount electrodes 16 and lead terminals 32 are joined. Therefore, cut portions 38 are formed in both sides 13a and 13b of the base 12 extending in the direction in which the resonating arms 18 extend (see FIG. 3(b)). The cut portions 38 are formed at locations where the area of the mount electrodes 16 is not reduced. The cut portions 38 formed in both sides have the same shape, are formed by etching, and can reduce the vibration leakage.

The above-described structure in which the ends of the resonating arms 18 have the curved portions 36 and the structure in which the cut portions 38 are formed in the base 12 may both be used at the same time (see FIG. 3(c)).

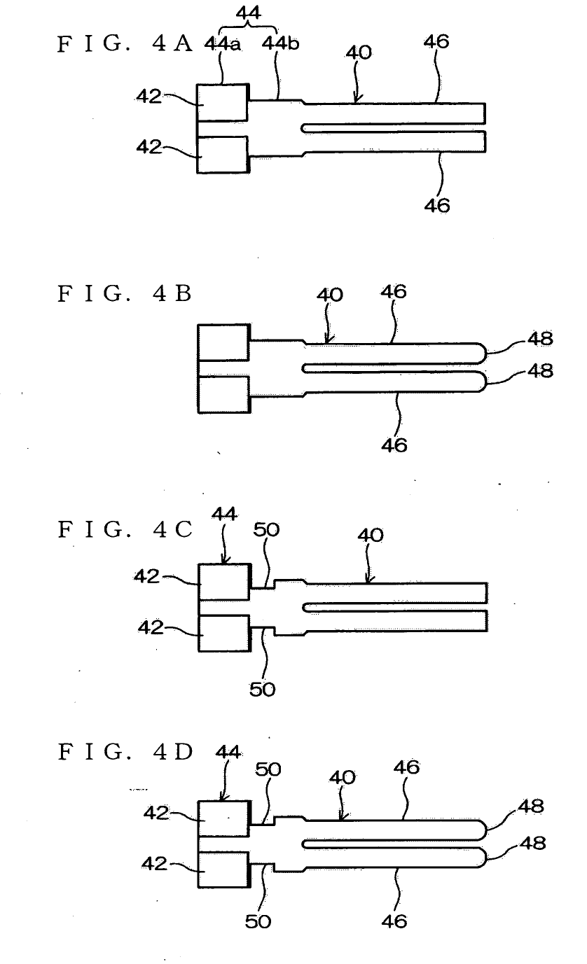

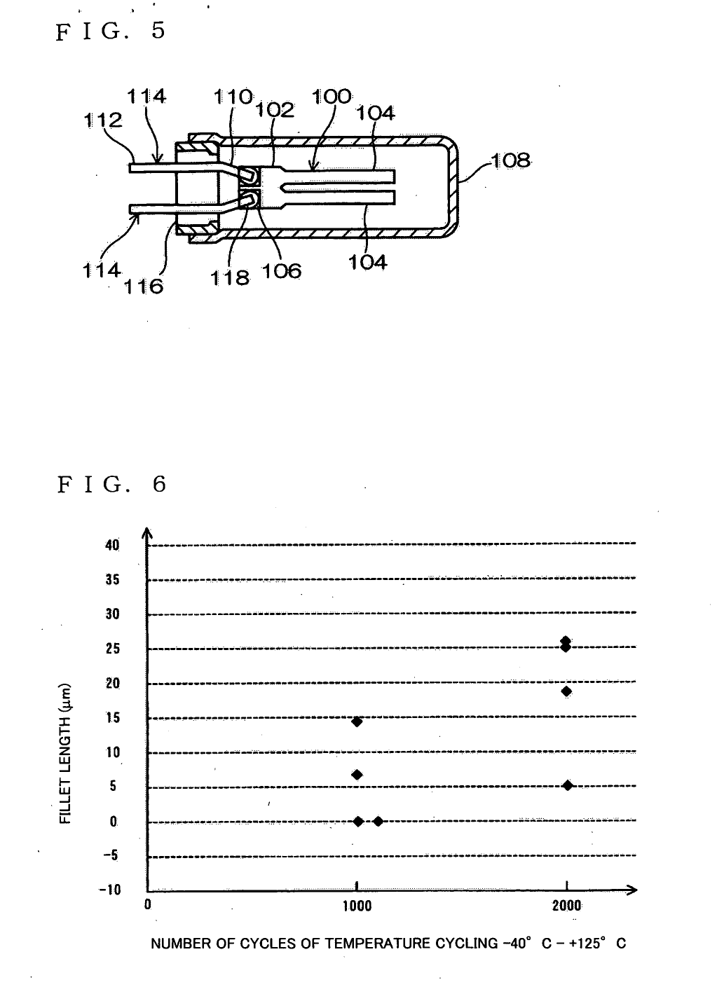

Next, a third embodiment of the present invention will be described in connection with FIG. 4. In FIG. 4, excitation electrodes disposed at resonating arms are not illustrated. The form of the tuning fork type piezoelectric resonator element in accordance with the third embodiment is different from that of the tuning fork type piezoelectric resonator element in accordance with the first embodiment, but the method for designing the resonator element and the advantages provided by the resonator element are the same. Therefore, parts corresponding to those in the first embodiment are not described below.

In accordance with the third embodiment shown in FIG. 4(a) the mount electrodes 42 are spaced from each other so that the mount electrodes 42 are not shorted by solder diffusion. The side of the base 44 of the tuning fork type piezoelectric resonator element 40 is formed so that only a base portion 44a where the mount electrodes 42 are formed is wider than the distance between lead terminals. Accordingly, this leaves a base portion 44b where the mount electrodes 42 are not formed which is thinner i.e. smaller in width than the base portion 44a where the mount electrodes 42 are formed. In order for the lengths of both sides of resonating arms 46 to be the same, the curvatures of the resonating arms 46 at locations where both sides of the resonating arms 46 and the base 44 are connected should be the same. The resonating arms 46 extend symmetrically from the base 44 with respect to a centerline of the base 44 extending in the direction of extension of the resonating arms 46. The width of the base 44 in the direction transverse to the arms 46 is smaller than the corresponding width of the base 12 in the first embodiment. Therefore, the distance between the resonating arms 46 of the tuning fork type piezoelectric resonator element 40 in accordance with the third embodiment is smaller than the distance between the resonating arms 18 in accordance with the first embodiment. Since the length and width of the resonating arms 46 correspond to the counter part length and width of the resonating arms 18 in accordance with the first embodiment, they have the same natural frequency.

Even the tuning fork type piezoelectric resonator element 40 in accordance with the third embodiment may have the forms illustrated in the second embodiment. In other words, ends of the resonating arms 46 may have convex curved portions 48 in order to prevent the resonating arms 46 from becoming, for example, chipped or bent (see FIG. 4(b)). In addition, cut portions 50 may be formed at locations of both sides of the base 44 where the area of the mount electrodes 42 is not reduced in order to reduce vibration leakage (see FIG. 4(c)). Further, the structure in which the ends of the resonating arms 46 have the curved portions 48 and the structure in which the cut portions 50 are formed in the base 44 may both be used at the same time (see FIG. 4(d)).

Although, in each of the above-described embodiments, the cylinder tuning fork type piezoelectric resonator 20 having the tuning fork type piezoelectric resonator element 10 or 40 inserted in the container 26 is described, a surface-mount tuning fork type piezoelectric resonator having one side of the above-described tuning fork type piezoelectric resonator element 10 or 40 mounted to a ceramic or metallic package may be used. In this case, the tuning fork type piezoelectric resonator element is mounted to the mount electrodes formed at the package.

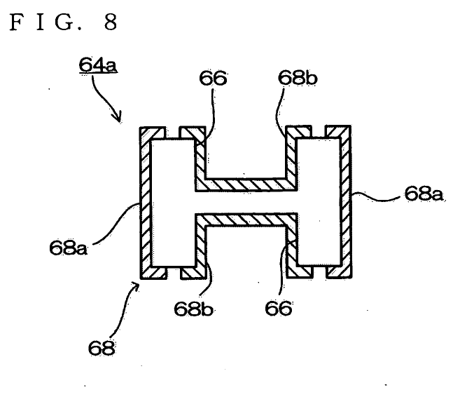

FIG. 7 is a plan view of a tuning fork type piezoelectric resonator element in accordance with a fourth embodiment of the present invention. In FIG. 7, a tuning fork type piezoelectric resonator element 60 comprises a base 62 and a pair of resonating arms 64 (64a and 64b) protruding from one end of the base 62. Each vibratory arm 64 has grooves 66 at its base end side so as to extend in the longitudinal direction of the resonating arms 64. The grooves 66 are formed at locations corresponding to the upper and lower surfaces of each vibratory arm 64. Therefore, as shown in FIG. 8, each vibratory arm 64 has an H shape in cross section. In the tuning fork type piezoelectric resonator element 60, excitation electrodes 68 and 70 are formed at the respective resonating arms 64. The excitation electrodes 68 and 70 comprise side electrode portions 68a and side electrode portions 70a, respectively, formed at both side surfaces of the resonating arms 64, and groove electrode portions 68b and groove electrode portions 70b, respectively, formed at inner surfaces defining the respective grooves 66. The side electrode portions 68a and the side electrode portions 70a formed at both side surfaces of the respective resonating arms 64 are connected to each other through an end electrode portion 68c and an end electrode portion 70c, respectively, formed at an end of its corresponding vibratory arm 64. The end electrode portions 68c and 70c are used to adjust the oscillatory frequency of the tuning fork type piezoelectric resonator element 60.

The groove electrode portions 68b and 70b are electrically connected to the side electrode portions of the respective other resonating arms 64. In other words, the groove electrode portions 68b of the vibratory arm 64a are electrically connected to the side electrode portions 70a of the other vibratory arm 64b. The groove electrode portions 70b of the vibratory arm 64b are electrically connected to the side electrode portions 68a of the vibratory arm 64a. In addition, the tuning fork type piezoelectric resonator element 60 has a pair of mount electrodes 72 (72a and 72b) formed on the base 62. The mount electrode 72a is connected to the excitation electrode 68, and the mount electrode 72b is connected to the excitation electrode 70. Cut portions 38 are formed in both sides of the base 62.

In the tuning fork type piezoelectric resonator element, the oscillatory frequency is basically determined by the width and length of the resonating arms. In the tuning fork type piezoelectric resonator element 60 for vehicle use in accordance with the embodiment, in order to increase temperature resistance cycle, a width c of the base 62 is greater than that in a related tuning fork type piezoelectric resonator element and the curvature of a forked portion 15 and that of shoulders 17 are small (that is, the radius of curvature is large). Therefore, in the tuning fork type piezoelectric resonator element 60 in accordance with the embodiment, when a width W of the resonating arms 64 is the same as the width of the resonating arms of a related tuning fork type piezoelectric resonator element, the width of the base end of the resonating arms 64 is large, so that the same advantage as that provided when the resonating arms 64 is shortened is essentially provided. Detailed investigations and experiments confirmed that, when the width W and a length b of the resonating arms 64 are the same as those of the related resonating arms, the oscillatory frequency of the tuning fork type piezoelectric resonator element 60 of the embodiment is less than the oscillatory frequency of a related tuning fork type piezoelectric resonator element comprising a base having a smaller width. Therefore, when the tuning fork type piezoelectric resonator element 60 of the embodiment having the same frequency as a related tuning fork type piezoelectric resonator element is to be formed, the length of the resonating arms 64 is made slightly longer than that of the resonating arms in the related tuning fork type piezoelectric resonator element in order to adjust the oscillatory frequency.

For example, when a tuning fork type piezoelectric vibrator having an oscillatory frequency of 32.768 kHz is to be formed, a related tuning fork type piezoelectric resonator element is formed so that, with reference to FIG. 7, a base length a=1102 μm, a base width c=640 μm, a vibratory arm length b=2358 μm, a vibratory arm width W=236 μm, an overall length L=3460 μm, and a curvature radius R of shoulders and a forked portion is equal to 66 μm, whereas the tuning fork type piezoelectric resonator element 60 of the embodiment is formed so that a length a of the base 62 is 1102 μm, a width c of the base 62 is 1000 μm, the length b of the resonating arms 64 is 2478 μm, the width W of the resonating arms 64 is 236 μm, an overall length L=3580 μm, and a curvature radius R of the shoulders 17 and the forked portion 15 is equal to 132 μm. In other words, the length b of the resonating arms 64 of the tuning fork type piezoelectric resonator element 60 of the embodiment is larger than that of the resonating arms of the related tuning fork type piezoelectric resonator element by 120 μm. In the tuning fork type piezoelectric resonator element 60 of the embodiment, the locations of formation of the cut portions 38, that is, a distance e from the other end of the base 62 is 570 to 680 μm, and a depth g of the cut portions 38 is 100 to 220 μm.

The oscillatory frequency of the tuning fork type piezoelectric resonator element 60 of the embodiment formed in this way is slightly less than 32.768 kHz. Therefore, the oscillatory frequency of the tuning fork type piezoelectric vibrator using the tuning fork type piezoelectric resonator element 60 of the embodiment is easily adjusted to a value of 32.768 kHz by removing the end electrode portions 68c and 70c by laser.

1. A tuning fork type piezoelectric resonator element comprising:
a base having opposite ends,
a plurality of resonating arms protruding from one end of the base; and
a plurality of mount electrodes disposed at the other end of the base in substantial parallel alignment with the resonating arms,
wherein the mount electrodes are spaced apart a minimum distance of at least 60 μm to prevent shorting of the mount electrodes when the tuning fork is subjected to temperature cycling.

2. The tuning fork type piezoelectric resonator element according to claim 1, further comprising a plurality of lead terminals corresponding in number to said mount electrodes with the lead terminals extending in a straight line direction parallel to said resonating arms at the connection with said mount electrodes, and
a solder conductive joining material for joining the lead terminals to the mount electrodes.

3. The tuning fork type piezoelectric resonator element according to claim 1 wherein the other end of the base has a width (length or height?)which allows the lead terminals to be linearly joined.

4. The tuning fork type piezoelectric resonator element according to claim 1, wherein each vibratory arm has two sides with each side having the same length, and with each vibratory arm extending symmetrically with respect to a centerline of the base.

5. The tuning fork type piezoelectric resonator element according to claim 2, wherein each vibratory arm has two sides with each side having the same length, and with each vibratory arm extending symmetrically with respect to a centerline of the base.

6. The tuning fork type piezoelectric resonator element according to claim 3, wherein each vibratory arm has two sides with each side having the same length, and with each vibratory arm extending symmetrically with respect to a centerline of the base.

7. The tuning fork type piezoelectric resonator element according to claim 1 wherein each vibratory arm is disposed inwardly relative to the sides of the base, and with the end of the base from which the arms extend having a curved portion with an arc shape disposed between the resonating arms and having shoulders extending from each arm to each opposite side thereof with the shoulders having the same curvature as the curved portion.

8. The tuning fork type piezoelectric resonator element according to claim 2 wherein each vibratory arm is disposed inwardly relative to the sides of the base, and with the end of the base from which the arms extend having a curved portion with an arc shape disposed between the resonating arms and having shoulders extending from each arm to each opposite side thereof with the shoulders having the same curvature as the curved portion.

9. The tuning fork type piezoelectric resonator element according to claim 4 wherein each vibratory arm is disposed inwardly relative to the sides of the base, and with the end of the base from which the arms extend having a curved portion with an arc shape disposed between the resonating arms and having shoulders extending from each arm to each opposite side thereof with the shoulders having the same curvature as the curved portion.

10. The tuning fork type piezoelectric resonator element according to claim 1 wherein each vibratory arm terminates at an end having a convex surface.

11. The tuning fork type piezoelectric resonator element according to claim 7 wherein each vibratory arm terminates at an end having a convex surface.

12. The tuning fork type piezoelectric resonator element according to claim 8 wherein each vibratory arm terminates at an end having a convex surface.

13. The tuning fork type piezoelectric resonator element according to claim 9 wherein each vibratory arm terminates at an end having a convex surface.

14. The tuning fork type piezoelectric resonator element according to claim 1 wherein both sides of the base extending in the direction in which the resonating arms extend have cut portions extending into the base in a transverse direction.

15. The tuning fork type piezoelectric resonator element according to claim 2 wherein both sides of the base extending in the direction in which the resonating arms extend have cut portions extending into the base in a transverse direction.

16. The tuning fork type piezoelectric resonator element according to claim 4 wherein both sides of the base extending in the direction in which the resonating arms extend have cut portions extending into the base in a transverse direction.

17. The tuning fork type piezoelectric resonator element according to claim 13 wherein both sides of the base extending in the direction in which the resonating arms extend have cut portions extending into the base in a transverse direction.

18. The tuning fork type piezoelectric resonator element according to any claim 1, wherein the width of the other end of the base extending perpendicularly to the resonating arms is greater than the width of said one end of the base.

19. The tuning fork type piezoelectric resonator element according to any claim 2, wherein the width of the other end of the base extending perpendicularly to the resonating arms is greater than the width of said one end of the base.

20. The tuning fork type piezoelectric resonator element according to any claim 4, wherein the width of the other end of the base extending perpendicularly to the resonating arms is greater than the width of said one end of the base.

21. The tuning fork type piezoelectric resonator element according to claim 8, wherein the width of the other end of the base extending perpendicularly to the resonating arms is greater than the width of said one end of the base.

22. A method for producing a tuning fork type piezoelectric resonator comprising a base having two sides and opposite ends, a plurality of mount electrodes disposed at one end of the base , a plurality of resonating arms extending from the opposite end of the base and lead terminals joined with a conductive joining material at said one end of the base to the mount electrodes, the method comprising the steps of:
separating the mount electrodes a sufficient minimum distance apart for preventing shorts caused by diffusion of the conductive joining material upon subjecting the resonator to thermal cycling;
connecting said lead terminals to said mount electrodes without forming a bend in the lead terminals at the end thereof adjacent the mount electrodes with the width of the base along each side thereof set to a value that permits the lead terminals to be linearly joined to the mount electrodes; and
symmetrically arranging the plurality the resonating arms with respect to the base so that any curvatures formed at the locations where the resonating arms are connected to the base are the same.

23. A method as defined in claim 22 wherein said minimum distance is at least 60 μm.
